(19) United States
(12) Patent Application Publication
(10) Pub. No.: US 2026/0282531 A1
(43) Pub. Date: Sep. 17, 2026

(54) SEMICONDUCTOR PACKAGE

(71) Applicant: SAMSUNG ELECTRONICS CO., LTD., Suwon-si (KR)

(72) Inventor: Sungmin Kim, Suwon-si (KR)

(73) Assignee: SAMSUNG ELECTRONICS CO., LTD., Suwon-si (KR)

(21) Appl. No.: 19/371,164

(22) Filed: Oct. 28, 2025

(30) Foreign Application Priority Data
Mar. 17, 2025 (KR) 10-2025-0033946

(51) Int. Cl. H10D 84/83; H10D 64/23; H10D 80/30; H10W 20/20; H10W 20/41; H10W 90/00; H10W 90/20; H10W 90/26

(52) U.S. Cl. CPC H10D 84/832; H10D 64/254; H10D 80/30; H10W 20/20; H10W 20/435; H10W 90/00; H10W 90/26; H10W 90/297; H10W 90/792

(57) ABSTRACT

A semiconductor package may include a first logic chip, and a second logic chip overlapping with the first logic chip. The first logic chip may include a first lower channel structure, a first lower source/drain pattern connected to the first lower channel structure, a first upper channel structure overlapping with the first lower channel structure, and a first upper source/drain pattern connected to the first upper channel structure. The second logic chip may include a second lower channel structure, a second lower source/drain pattern connected to the second lower channel structure, a second upper channel structure overlapping with the second lower channel structure, and a second upper source/drain pattern connected to the second upper channel structure.

### CROSS-REFERENCE TO RELATED APPLICATION

This U.S. non-provisional patent application claims priority under 35 U.S.C. §119 to Korean Patent Application No. 10-2025-0033946, filed on Mar. 17, 2025, in the Korean Intellectual Property Office, the disclosure of which is hereby incorporated by reference in its entirety.

### BACKGROUND

### 1. Field

Some embodiments of the present disclosure relate to a semiconductor package and a method of fabricating the semiconductor package.

### 2. Description of Background Art

A semiconductor package may be a structure that includes an integrated circuit chips that is suitable for use in electronics. The semiconductor package may include a semiconductor chip on a printed circuit board, and may include bonding wires or bumps that electrically connect the semiconductor chip and the printed circuit board. With the development of the electronics industry, various studies for improving the reliability of semiconductor packages have been conducted.

### SUMMARY

According to some embodiments of the present disclosure, a semiconductor package may include: a first logic chip; and a second logic chip overlapping with the first logic chip, wherein the first logic chip includes: a first lower channel structure; a first lower source/drain pattern connected to the first lower channel structure; a first upper channel structure overlapping with the first lower channel structure; and a first upper source/drain pattern connected to the first upper channel structure, and wherein the second logic chip includes: a second lower channel structure; a second lower source/drain pattern connected to the second lower channel structure; a second upper channel structure overlapping with the second lower channel structure; and a second upper source/drain pattern connected to the second upper channel structure.

According to some embodiments of the present disclosure, a semiconductor package may include: a base structure; a first logic chip electrically connected to the base structure; and a second logic chip overlapping with the first logic chip, and electrically connected to the base structure, wherein the first logic chip includes: first lower semiconductor patterns; a first lower source/drain pattern connected to the first lower semiconductor patterns; first upper semiconductor patterns overlapping with the first lower semiconductor patterns; and a first upper source/drain pattern connected to the first upper semiconductor patterns, and wherein the second logic chip includes: second lower semiconductor patterns; a second lower source/drain pattern connected to the second lower semiconductor patterns; second upper semiconductor patterns overlapping with the second lower semiconductor patterns; and a second upper source/drain pattern connected to the second upper semiconductor patterns.

According to some embodiments of the present disclosure, a semiconductor package may include: a base structure; a chip structure electrically connected to the base structure; and a molding layer surrounding the chip structure in a horizontal direction, wherein the chip structure includes: a base chip; a first logic chip overlapping with the base chip; and a second logic chip overlapping with the base chip and the first logic chip, wherein the first logic chip includes: a first substrate; a first lower source/drain pattern connected to the first substrate; first lower semiconductor patterns connected to the first lower source/drain pattern; a first upper source/drain pattern overlapping with the first lower source/drain pattern; and first upper semiconductor patterns connected to the first upper source/drain pattern, and wherein the second logic chip includes: a second substrate; a second lower source/drain pattern connected to the second substrate; second lower semiconductor patterns connected to the second lower source/drain pattern; a second upper source/drain pattern overlapping with the second lower source/drain pattern; and second upper semiconductor patterns connected to the second upper source/drain pattern.

### BRIEF DESCRIPTION OF DRAWINGS

FIG. 1A is a cross-sectional view of a semiconductor package according to some embodiments.

FIG. 1B is an enlarged view of a region Q1 of FIG. 1A.

FIGS. 2A, 2B and 2C are diagrams for describing a method for manufacturing a semiconductor package according to FIGS. 1A and 1B.

FIG. 3 is an enlarged cross-sectional view of a semiconductor package according to some embodiments.

FIG. 4 is a cross-sectional view of a semiconductor package according to some embodiments.

FIG. 5A is a cross-sectional view of a semiconductor package according to some embodiments.

FIG. 5B is an enlarged view of a region Q2 of FIG. 5A.

FIGS. 6A, 6B, 6C and 6D are diagrams for describing a method of manufacturing a semiconductor package according to FIGS. 5A and 5B.

### DETAILED DESCRIPTION

Non-limiting example embodiments of the present disclosure will now be described more fully with reference to the accompanying drawings, in which example embodiments are shown.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

Hereinafter, a semiconductor package and a manufacturing method thereof according to some embodiments of the present disclosure will be described in detail with reference to the drawings.

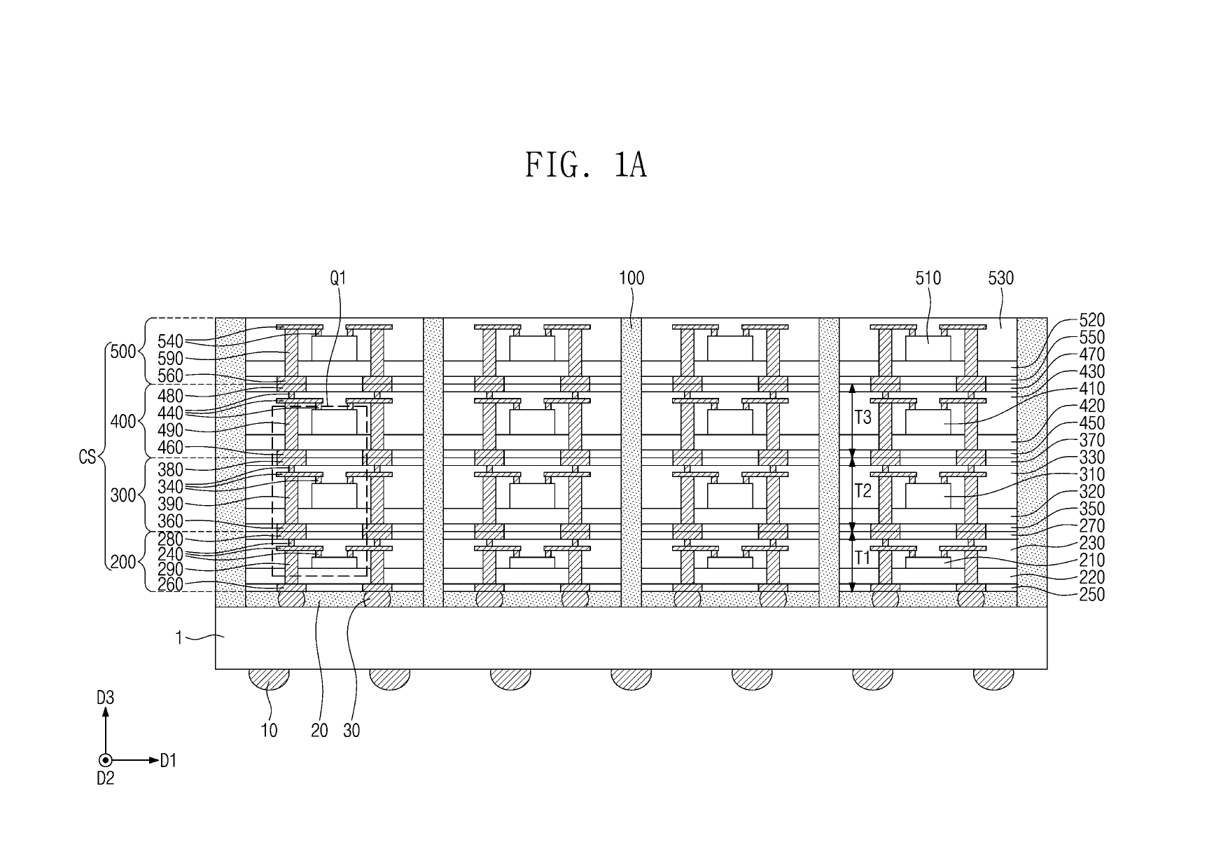

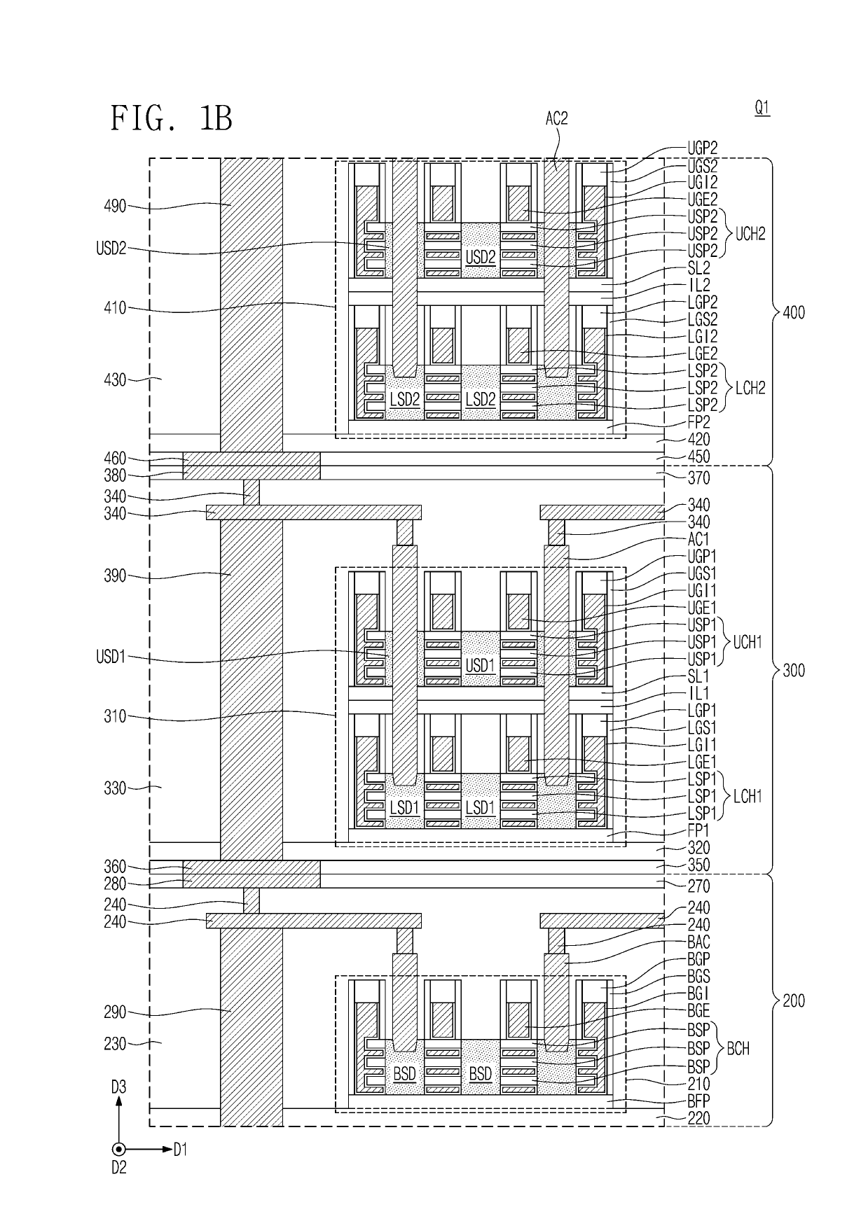

FIG. 1A is a cross-sectional view of a semiconductor package according to some embodiments. FIG. 1B is an enlarged view of a region Q1 of FIG. 1A.

Referring to FIG. 1A, a semiconductor package may include a terminal 10, a base structure 1, a bump 30, a chip structure CS, an underfill layer 20, and a molding layer 100.

The base structure 1 may have a shape of a plate extending along a plane defined by a first direction D1 and a second direction D2. The first direction D1 and the second direction D2 may intersect with each other. As an example, the first direction D1 and the second direction D2 may be horizontal directions orthogonal to each other. The base structure 1 may be, for example, a printed circuit board (PCB), a silicon interposer, or a redistribution substrate.

The terminal 10 may be connected to the base structure 1. The terminal 10 may include a conductive material.

The chip structure CS may be mounted on the base structure 1. The chip structure CS may be electrically connected to the base structure 1. The bump 30 may be provided between the chip structure CS and the base structure 1. The bump 30 may include a conductive material. The underfill layers 20 may be provided between the chip structure CS and the base structure 1. The underfill layer 20 may include a polymer material.

The molding layer 100 may surround the chip structure CS. The molding layer 100 may be provided on the base structure 1. The molding layer 100 may include a polymer material.

The chip structure CS may include a base chip 200, a first logic chip 300, a second logic chip 400, and a third logic chip 500. Although the number of logic chips (e.g., the first logic chip 300, the second logic chip 400, and the third logic chip 500) of the chip structure CS is shown and described as being three, the number of logic chips (e.g., the first logic chip 300, the second logic chip 400, and the third logic chip 500) of the chip structure CS may not be limited thereto. In some embodiments, the number of logic chips of the chip structure CS may be two, four, or more.

The base chip 200, the first logic chip 300, the second logic chip 400, and the third logic chip 500 may overlap with each other in a third direction D3. The third direction D3 may intersect the first direction D1 and the second direction D2. As an example, the third direction D3 may be a vertical direction orthogonal to the first direction D1 and the second direction D2. The base chip 200, the first logic chip 300, the second logic chip 400, and the third logic chip 500 may be electrically connected to the base structure 1.

The base chip 200, the first logic chip 300, the second logic chip 400, and the third logic chip 500 may include, for example, a central processing unit (CPU), a graphic processing unit (GPU), or an application processor (AP).

The base chip 200 may include a base logic cell structure 210, a base substrate 220, a base insulating structure 230, a base conductive structure 240, a base lower insulating layer 250, a base lower pad 260, a base upper insulating layer 270, a base upper pad 280, and a base through via 290.

The base substrate 220 may be a semiconductor substrate, an insulator substrate, or a semiconductor-on-insulator (SOI) substrate. The semiconductor substrate may include, for example, silicon, germanium, silicon-germanium, GaP, or GaAs.

The base logic cell structure 210 may be connected to an upper surface of the base substrate 220.

The base conductive structure 240 may be electrically connected to the base logic cell structure 210. The base conductive structure 240 may include at least one from among a conductive via, a conductive line, and a conductive pad. The base conductive structure 240 may include a conductive material.

The base insulating structure 230 may surround the base logic cell structure 210 and the base conductive structure 240. The base conductive structure 240 may be disposed within the base insulating structure 230. The base insulating structure 230 may be connected to an upper surface of the base substrate 220. The base insulating structure 230 may include an insulating material. In some embodiments, the base insulating structure 230 may include multiple layers including, for example, a plurality of insulating layers.

The base lower pad 260 may be in contact with the bump 30. The base lower pad 260 may include a conductive material.

The base lower insulating layer 250 may surround the base lower pad 260. The base lower pad 260 may be disposed in the base lower insulating layer 250. The base lower insulating layer 250 may include an insulating material. In some embodiments, the base lower insulating layer 250 may include multiple layers including, for example, a plurality of insulating layers.

The base upper pad 280 may be in contact with the base conductive structure 240. The base upper pad 280 may include a conductive material.

The base upper insulating layer 270 may surround the base upper pad 280. The base upper pad 280 may be disposed in the base upper insulating layer 270. The base upper insulating layer 270 may include an insulating material. In some embodiments, the base upper insulating layer 270 may include multiple layers including, for example, a plurality of insulating layers.

The base through via 290 may penetrate the base substrate 220 in the third direction D3. At least a portion of the base through via 290 may be surrounded by the base substrate 220. The base through via 290 may be in contact with the base lower pad 260 and the base conductive structure 240.

The first logic chip 300 may include a first logic cell structure 310, a first substrate 320, a first insulating structure 330, a first conductive structure 340, a first lower insulating layer 350, a first lower pad 360, a first upper insulating layer 370, a first upper pad 380, and a first through via 390.

The first substrate 320 may be a semiconductor substrate, an insulator substrate, or a semiconductor-on-insulator (SOI) substrate.

The first logic cell structure 310 may be connected to an upper surface of the first substrate 320.

The first conductive structure 340 may be electrically connected to the first logic cell structure 310. The first conductive structures 340 may include at least one from among a conductive via, a conductive line, and a conductive pad. The first conductive structure 340 may include a conductive material.

The first insulating structure 330 may surround the first logic cell structure 310 and the first conductive structure 340. The first conductive structure 340 may be disposed in the first insulating structure 330. The first insulating structure 330 may be connected to the upper surface of the first substrate 320. The first insulating structure 330 may include an insulating material. In some embodiments, the first insulating structure 330 may include multiple layers including, for example, a plurality of insulating layers.

The first lower pad 360 may be in contact with the base upper pad 280. The first lower pad 360 may include a conductive material.

The first lower insulating layer 350 may surround the first lower pad 360. The first lower pad 360 may be disposed in the first lower insulating layer 350. The first lower insulating layer 350 may include an insulating material. In some embodiments, the first lower insulating layer 350 may include multiple layers including, for example, a plurality of insulating layers.

The first logic chip 300 and the base chip 200 may be hybrid-bonded. The first lower pad 360 and the base upper pad 280 may be bonded to each other, and the first lower insulating layer 350 and the base upper insulating layer 270 may be bonded with each other.

In some embodiments, the first logic chip 300 and the base chip 200 may be electrically connected by a bump between the first logic chip 300 and the base chip 200.

The first upper pad 380 may be in contact with the first conductive structure 340. The first upper pad 380 may include a conductive material.

The first upper insulating layer 370 may surround the first upper pad 380. The first upper pad 380 may be disposed in the first upper insulating layer 370. The first upper insulating layer 370 may include an insulating material. In some embodiments, the first upper insulating layer 370 may include multiple layers including, for example, a plurality of insulating layers.

The first through via 390 may penetrate the first substrate 320 in the third direction D3. At least a portion of the first through via 390 may be surrounded by the first substrate 320. The first through via 390 may be in contact with the first lower pad 360 and the first conductive structure 340.

The second logic chip 400 may include a second logic cell structure 410, a second substrate 420, a second insulating structure 430, a second conductive structure 440, a second lower insulating layer 450, a second lower pad 460, a second upper insulating layer 470, a second upper pad 480, and a second through via 490.

The second substrate 420 may be a semiconductor substrate, an insulator substrate, or a semiconductor-on-insulator (SOI) substrate.

The second logic cell structure 410 may be connected to an upper surface of the second substrate 420.

The second conductive structure 440 may be electrically connected to the second logic cell structure 410. The second conductive structures 440 may include at least one from among a conductive via, a conductive line, and a conductive pad. The second conductive structure 440 may include a conductive material.

The second insulating structure 430 may surround the second logic cell structure 410 and the second conductive structure 440. The second conductive structure 440 may be disposed in the second insulating structure 430. The second insulating structure 430 may be connected to the upper surface of the second substrate 420. The second insulating structure 430 may include an insulating material. In some embodiments, the second insulating structure 430 may include multiple layers including, for example, a plurality of insulating layers.

The second lower pad 460 may be in contact with the first upper pad 380. The second lower pad 460 may include a conductive material.

The second lower insulating layer 450 may surround the second lower pad 460. The second lower pad 460 may be disposed in the second lower insulating layer 450. The second lower insulating layer 450 may include an insulating material. In some embodiments, the second lower insulating layer 450 may include multiple layers including, for example, a plurality of insulating layers.

The second logic chip 400 and the first logic chip 300 may be hybrid-bonded. The second lower pad 460 and the first upper pad 380 may be bonded to each other, and the second lower insulating layer 450 and the first upper insulating layer 370 may be bonded to each other.

In some embodiments, the second logic chip 400 and the first logic chip 300 may be electrically connected by a bump between the second logic chip 400 and the first logic chip 300.

The second upper pad 480 may be in contact with the second conductive structure 440. The second upper pad 480 may include a conductive material.

The second upper insulating layer 470 may surround the second upper pad 480. The second upper pad 480 may be disposed in the second upper insulating layer 470. The second upper insulating layer 470 may include an insulating material. In some embodiments, the second upper insulating layer 470 may include multiple layers including, for example, a plurality of insulating layers.

The second through via 490 may penetrate the second substrate 420 in the third direction D3. At least a portion of the second through via 490 may be surrounded by the second substrate 420. The second through via 490 may be in contact with the second lower pad 460 and the second conductive structure 440.

The third logic chip 500 may include a third logic cell structure 510, a third substrate 520, a third insulating structure 530, a third conductive structure 540, a third lower insulating layer 550, a third lower pad 560, and a third through via 590.

The third substrate 520 may be a semiconductor substrate, an insulator substrate, or a semiconductor-on-insulator (SOI) substrate.

The third logic cell structure 510 may be connected to an upper surface of the third substrate 520.

The third conductive structure 540 may be electrically connected to the third logic cell structure 510. The third conductive structures 540 may include at least one from among a conductive via, a conductive line, and a conductive pad. The third conductive structure 540 may include a conductive material.

The third insulating structure 530 may surround the third logic cell structure 510 and the third conductive structure 540. The third conductive structure 540 may be disposed in the third insulating structure 530. The third insulating structure 530 may be connected to the upper surface of the third substrate 520. The third insulating structure 530 may include an insulating material. In some embodiments, the third insulating structure 530 may include multiple layers including, for example, a plurality of insulating layers.

The third lower pad 560 may be in contact with the second upper pad 480. The third lower pad 560 may include a conductive material.

The third lower insulating layer 550 may surround the third lower pad 560. The third lower pad 560 may be disposed in the third lower insulating layer 550. The third lower insulating layer 550 may include an insulating material. In some embodiments, the third lower insulating layer 550 may include multiple layers including, for example, a plurality of insulating layers.

The third logic chip 500 and the second logic chip 400 may be hybrid-bonded. The third lower pad 560 and the second upper pad 480 may be bonded to each other, and the third lower insulating layer 550 and the second upper insulating layer 470 may be bonded to each other.

In some embodiments, the third logic chip 500 and the second logic chip 400 may be electrically connected by a bump between the third logic chip 500 and the second logic chip 400.

The third through via 590 may penetrate the third substrate 520 in the third direction D3. At least a portion of the third through via 590 may be surrounded by the third substrate 520. The third through via 590 may be in contact with the third lower pad 560 and the third conductive structure 540.

A thickness T1 of the base chip 200 in the third direction D3 may be less than a thickness T2 of the first logic chip 300 in the third direction D3 and a thickness T3 of the second logic chip 400 in the third direction D3. The thickness T2 of the first logic chip 300 in a third direction D3 and the thickness T3 of the second logic chip 400 in the third direction D3 may be the same.

Referring to FIG. 1B, the base logic cell structure 210 may include a base fin pattern BFP, a base channel structure BCH, a base source/drain pattern BSD, a base gate electrode BGE, a base gate spacer BGS, a base gate insulating layer BGI, a base gate capping pattern BGP, and a base active contact BAC.

The base fin pattern BFP, the base channel structure BCH, the base source/drain pattern BSD, the base gate electrode BGE, the base gate spacer BGS, the base gate insulating layer BGI, the base gate capping pattern BGP, and the base active contact BAC of the base logic cell structure 210 may be surrounded by the base insulating structure 230.

The base fin pattern BFP may be a portion of the base substrate 220. A portion protruding from the upper surface of the base substrate 220 in the third direction D3 may be defined as the base fin pattern BFP.

The base source/drain pattern BSD may be connected to an upper surface of the base fin pattern BFP.

The base channel structure BCH may be connected to the base source/drain pattern BSD. The base channel structure BCH may include base semiconductor patterns BSP overlapping with each other in the third direction D3. The base semiconductor patterns BSP may be connected to the base source/drain pattern BSD.

The base gate electrode BGE may overlap with the base semiconductor patterns BSP of the base channel structure BCH in the third direction D3. The base gate electrode BGE may include portions provided between the base semiconductor patterns BSP. The base gate electrode BGE and the base semiconductor patterns BSP may constitute a three-dimensional field effect transistor (e.g., a multi-bridge channel field-effect transistor (MBCFET) or a gate-all-around field effect transistor (GAAFET)).

The base gate insulating layer BGI may be provided. The base gate insulating layer BGI may be in contact with the base gate electrode BGE, the base semiconductor patterns BSP of the base channel structure BCH, and the base source/drain pattern BSD. The base gate insulating layer BGI may separate (e.g., electrically insulate) the base gate electrode BGE from the base semiconductor patterns BSP and the base source/drain pattern BSD.

The base gate spacer BGS may be provided. A pair of base gate spacers BGS may be disposed on opposite sides of the base gate electrode BGE.

The base gate capping pattern BGP may be provided. The base gate capping pattern BGP may be provided on the base gate electrode BGE.

The base active contact BAC may be electrically connected to the base source/drain pattern BSD. The base source/drain pattern BSD may be electrically connected to the base conductive structure 240 by the base active contact BAC.

The first logic cell structure 310 may include a first fin pattern FP1, a first lower channel structure LCH1, a first upper channel structure UCH1, a first lower source/drain pattern LSD1, a first upper source/drain pattern USD1, a first lower gate electrode LGE1, a first upper gate electrode UGE1, a first lower gate spacer LGS1, a first upper gate spacer UGS1, a first lower gate insulating layer LGI1, a first upper gate insulating layer UGI1, a first lower gate capping pattern LGP1, a first upper gate capping pattern UGP1, a first active contact AC1, a first interlayer insulating layer IL1, and a first semiconductor layer SL1.

The first fin pattern FP1, the first lower channel structure LCH1, the first upper channel structure UCH1, the first lower source/drain pattern LSD1, the first upper source/drain pattern USD1, the first lower gate electrode LGE1, the first upper gate electrode UGE1, the first lower gate spacer LGS1, the first upper gate spacer UGS1, the first lower gate insulating layer LGI1, the first upper gate insulating layer UGI1, the first lower gate capping pattern LGP1, the first upper gate capping pattern UGP1, the first active contact AC1, the first interlayer insulating layer IL1, and the first semiconductor layer SL1 of the first logic cell structure 310 may be surrounded by the first insulating structure 330.

The first fin pattern FP1 may be a portion of the first substrate 320. A portion protruding from the upper surface of the first substrate 320 in the third direction D3 may be defined as the first fin pattern FP1.

The first lower source/drain pattern LSD1 may be connected to an upper surface of the first fin pattern FP1.

The first lower channel structure LCH1 may be connected to the first lower source/drain pattern LSD1. The first lower channel structure LCH1 may include first lower semiconductor patterns LSP1 overlapping with each other in the third direction D3. The first lower semiconductor patterns LSP1 may be connected to the first lower source/drain pattern LSD1.

The first lower gate electrode LGE1 may overlap with the first lower semiconductor patterns LSP1 of the first lower channel structure LCH1 in the third direction D3. The first lower gate electrode LGE1 may include portions provided between the first lower semiconductor patterns LSP1. The first lower gate electrode LGE1 and the first lower semiconductor patterns LSP1 may constitute a three-dimensional field effect transistor (e.g., MBCFET or GAAFET).

The first lower gate insulating layer LGI1 may be provided. The first lower gate insulating layer LGI1 may be in contact with the first lower gate electrode LGE1, the first lower semiconductor patterns LSP1 of the first lower channel structure LCH1, and the first lower source/drain pattern LSD1. The first lower gate insulating layer LGI1 may separate (e.g., electrically insulate) the first lower gate electrode LGE1 from the first lower semiconductor patterns LSP1 and the first lower source/drain pattern LSD1.

The first lower gate spacer LGS1 may be provided. A pair of first lower gate spacers LGS1 may be disposed on opposite sides of the first lower gate electrode LGE1.

The first lower gate capping pattern LGP1 may be provided. The first lower gate capping pattern LGP1 may be provided on the first lower gate electrode LGE1.

The first interlayer insulating layer IL1 may be provided on the first lower gate capping pattern LGP1. The first semiconductor layer SL1 may be provided on the first interlayer insulating layer IL1.

The first upper source/drain pattern USD1 may be connected to an upper surface of the first semiconductor layer SL1. The first upper source/drain pattern USD1 may overlap the first lower source/drain patterns LSD1 in the third direction D3.

The first upper channel structure UCH1 may be connected to the first upper source/drain pattern USD1. The first upper channel structure UCH1 may include first upper semiconductor patterns USP1 overlapping in the third direction D3. The first upper semiconductor patterns USP1 may be connected to the first upper source/drain pattern USD1. The first lower semiconductor patterns LSP1 of the first lower channel structure LCH1 may overlap the first upper semiconductor patterns USP1 of the first upper channel structure UCH1 in the third direction D3.

The first upper gate electrode UGE1 may overlap the first upper semiconductor patterns USP1 of the first upper channel structure UCH1 in the third direction D3. The first upper gate electrode UGE1 may include portions provided between the first upper semiconductor patterns USP1. The first upper gate electrode UGE1 and the first upper semiconductor patterns USP1 may constitute a three-dimensional field effect transistor (e.g., MBCFET or GAAFET).

The first upper gate insulating layer UGI1 may be provided. The first upper gate insulating layer UGI1 may be in contact with the first upper gate electrode UGE1, the first upper semiconductor patterns USP1 of the first upper channel structure UCH1, and the first upper source/drain pattern USD1. The first upper gate insulating layer UGI1 may separate (e.g., electrically insulate) the first upper gate electrode UGE1 from the first upper semiconductor patterns USP1 and the first upper source/drain pattern USD1.

The first upper gate spacer UGS1 may be provided. A pair of first upper gate spacers UGS1 may be disposed on opposite sides of the first upper gate electrode UGE1.

The first upper gate capping pattern UGP1 may be provided. The first upper gate capping pattern UGP1 may be provided on the first upper gate electrode UGE1.

The first active contact AC1 may be electrically connected to the first lower source/drain pattern LSD1 and the first upper source/drain pattern USD1. The first lower source/drain pattern LSD1 and the first upper source/drain pattern USD1 may be electrically connected to the first conductive structure 340 by the first active contact AC1. The first active contact AC1 may penetrate the first interlayer insulating layer IL1 and the first semiconductor layer SL1 in the third direction D3.

The first semiconductor layer SL1 and the first interlayer insulating layer IL1 may be provided between the first lower semiconductor patterns LSP1 of the first lower channel structure LCH1 and the first upper semiconductor patterns USP1 of the first upper channel structure UCH1.

The first semiconductor layer SL1 and the first interlayer insulating layer IL1 may be provided between the first lower source/drain pattern LSD1 and the first upper source/drain pattern USD1. The first upper source/drain pattern USD1 may be in contact with the first semiconductor layer SL1.

The first semiconductor layer SL1 may be provided between the first lower gate electrode LGE1 and the first upper gate electrode UGE1.

The second logic cell structure 410 may have a structure similar to a structure of the first logic cell structure 310.

The second logic cell structure 410 may include a second fin pattern FP2, a second lower channel structure LCH2, a second upper channel structure UCH2, a second lower source/drain pattern LSD2, a second upper source/drain pattern USD2, a second lower gate electrode LGE2, a second upper gate electrode UGE2, a second lower gate spacer LGS2, a second upper gate spacer UGS2, a second lower gate insulating layer LGI2, a second upper gate insulating layer UGI2, a second lower gate capping pattern LGP2, a second upper gate capping pattern UGP2, a second active contact AC2, a second interlayer insulating layer IL2, and a second semiconductor layer SL2.

The first lower source/drain patterns LSD1, the first upper source/drain pattern USD1, the first lower semiconductor patterns LSP1, and the first upper semiconductor patterns USP1 may be disposed between the first substrate 320 and the second substrate 420.

Second lower semiconductor patterns LSP2 of the second lower channel structure LCH2 may be connected to the second lower source/drain pattern LSD2. Second upper semiconductor patterns USP2 of the second upper channel structure UCH2 may be connected to the second upper source/drain pattern USD2. The second lower semiconductor patterns LSP2 of the second lower channel structure LCH2 may overlap with the second upper semiconductor patterns USP2 of the second upper channel structure UCH2 in the third direction D3. The second upper source/drain pattern USD2 may overlap with the second lower source/drain pattern LSD2 in the third direction D3. The second lower source/drain pattern LSD2 may be connected to an upper surface of the second substrate 420.

The base source/drain pattern BSD, the first lower source/drain patterns LSD1, the second lower source/drain patterns LSD2, the first upper source/drain patterns USD1, and the second upper source/drain patterns USD2 may be epitaxial patterns formed by a selective epitaxial growth (SEG) process. The base source/drain pattern BSD, the first lower source/drain patterns LSD1, the second lower source/drain patterns LSD2, the first upper source/drain patterns USD1, and the second upper source/drain patterns USD2 may include a semiconductor material. As an example, the base source/drain pattern BSD, the first lower source/drain patterns LSD1, the second lower source/drain patterns LSD2, the first upper source/drain patterns USD1, and the second upper source/drain patterns USD2 may include at least one of silicon (Si), silicon-germanium (SiGe), or germanium (Ge). The base source/drain pattern BSD, the first lower source/drain patterns LSD1, the second lower source/drain patterns LSD2, the first upper source/drain patterns USD1, and the second upper source/drain patterns USD2 may be doped with dopants.

In some embodiments, the base semiconductor patterns BSP, the first lower semiconductor patterns LSP1, the second lower semiconductor patterns LSP2, the first upper semiconductor patterns USP1, and the second upper semiconductor patterns USP2 may include silicon (Si). For example, the base semiconductor patterns BSP, the first lower semiconductor patterns LSP1, the second lower semiconductor patterns LSP2, the first upper semiconductor patterns USP1, and the second upper semiconductor patterns USP2 may include crystalline silicon. In some embodiments, the base semiconductor patterns BSP, the first lower semiconductor patterns LSP1, the second lower semiconductor patterns LSP2, the first upper semiconductor patterns USP1, and the second upper semiconductor patterns USP2 may include silicon-germanium (SiGe).

The base gate electrode BGE, the first lower gate electrode LGE1, the second lower gate electrode LGE2, the first upper gate electrode UGE1, and the second upper gate electrode UGE2 may include a conductive material.

The base gate insulating layer BGI, the first lower gate insulating layer LGI1, the second lower gate insulating layer LGI2, the first upper gate insulating layer UGI1, and the second upper gate insulating layer UGI2 may include an insulating material. As an example, the base gate insulating layer BGI, the first lower gate insulating layer LGI1, the second lower gate insulating layer LGI2, the first upper gate insulating layer UGI1, and the second upper gate insulating layer UGI2 may include an oxide.

The base gate spacer BGS, the first lower gate spacers LGS1, the second lower gate spacers LGS2, the first upper gate spacers UGS1, and the second upper gate spacers UGS2 may include an insulating material.

The base gate capping pattern BGP, the first lower gate capping pattern LGP1, the second lower gate capping pattern LGP2, the first upper gate capping pattern UGP1, and the second upper gate capping pattern UGP2 may include an insulating material.

The base active contact BAC, the first active contact AC1, and the second active contact AC2 may include a conductive material.

The first interlayer insulating layer IL1 and the second interlayer insulating layer IL2 may include an insulating material. The first semiconductor layer SL1 and the second semiconductor layer SL2 may include a semiconductor material. For example, the first semiconductor layer SL1 and the second semiconductor layer SL2 may include silicon or germanium.

The third logic cell structure 510 of the third logic chip 500 may have a structure similar to a structure of the first logic cell structure 310 and a structure of the second logic cell structure 410.

In some embodiments, the base logic cell structure 210 of the base chip 200 may have a structure similar to the structure of the first logic cell structure 310 and the structure of the second logic cell structure 410. In a semiconductor package according to some embodiments, each of the logic chips may include the logic cell structure including an upper transistor and a lower transistor. Accordingly, a thickness of the chip structure in the third direction D3 may be reduced, and a size of the semiconductor package may be reduced. Accordingly, a degree of integration of the semiconductor package may be improved, packaging stress may be alleviated, and heat dissipation may be improved.

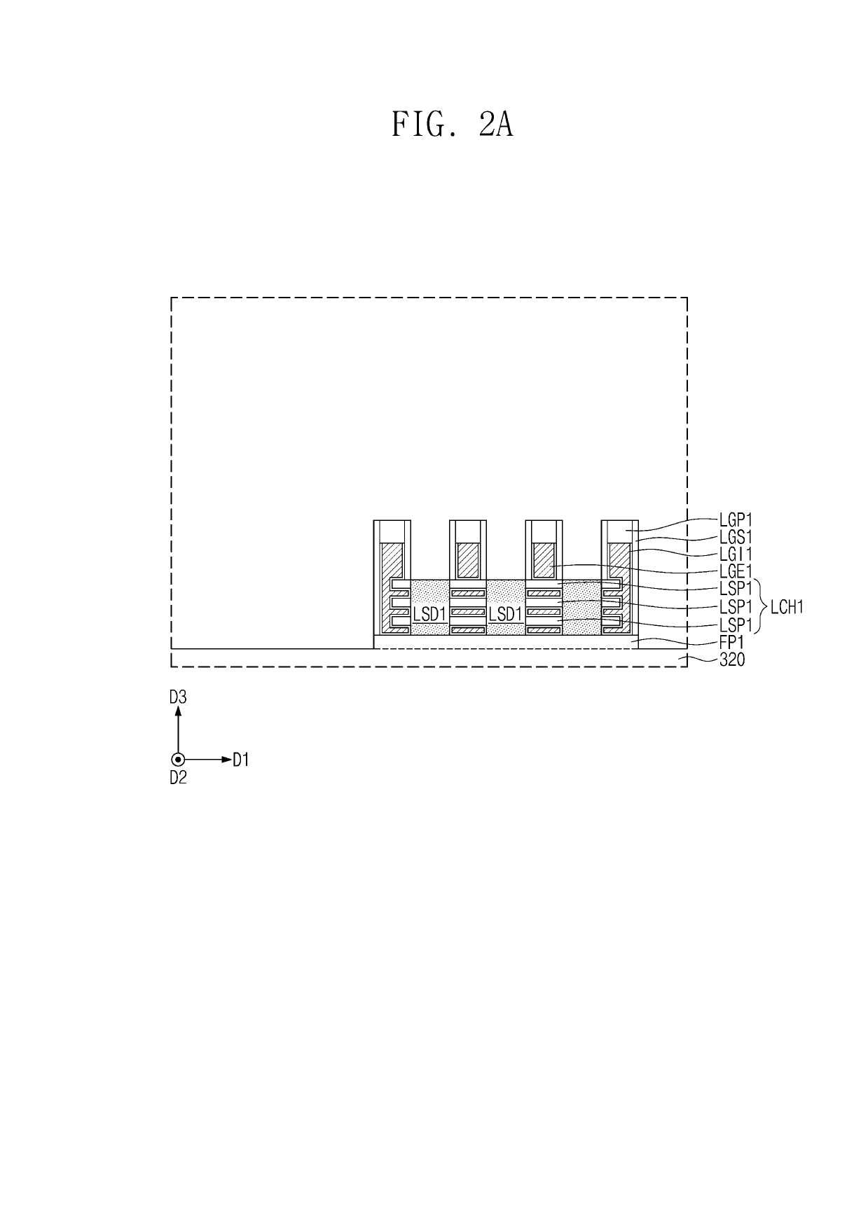

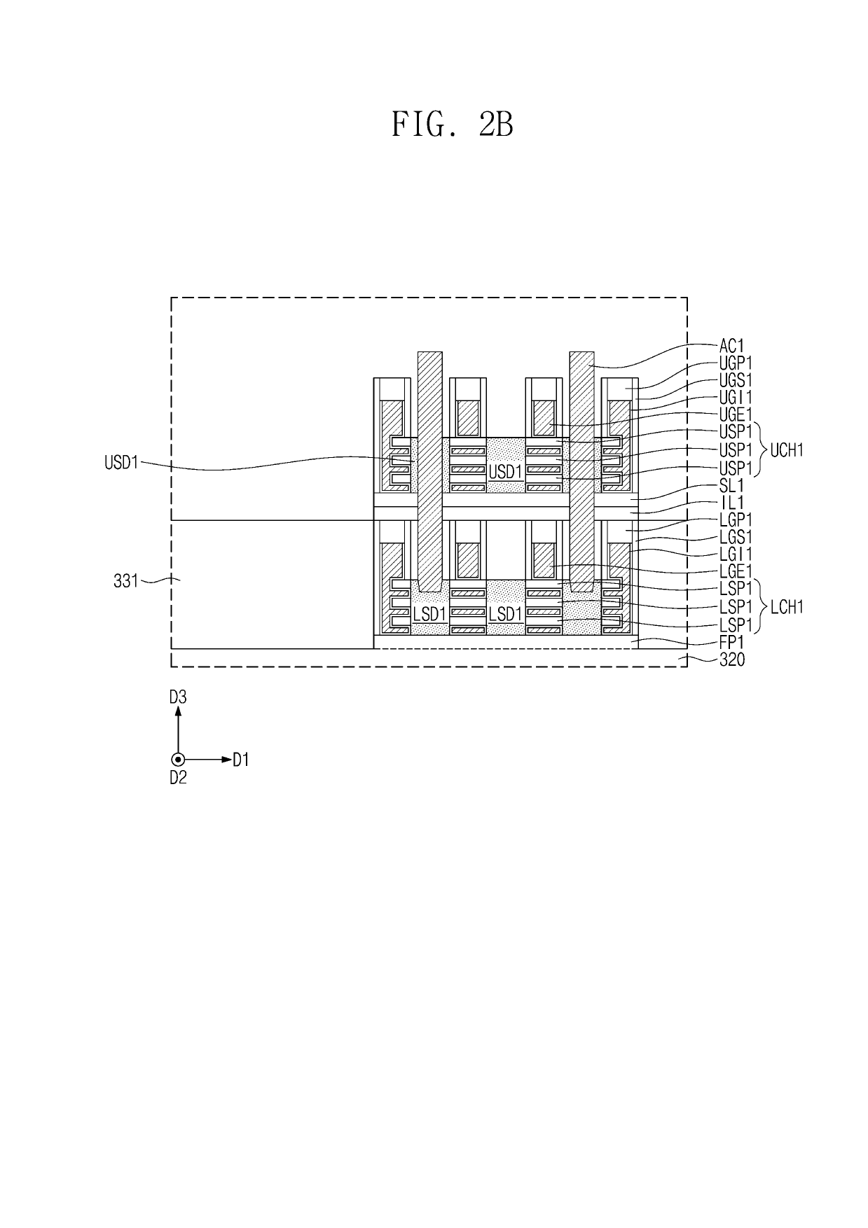

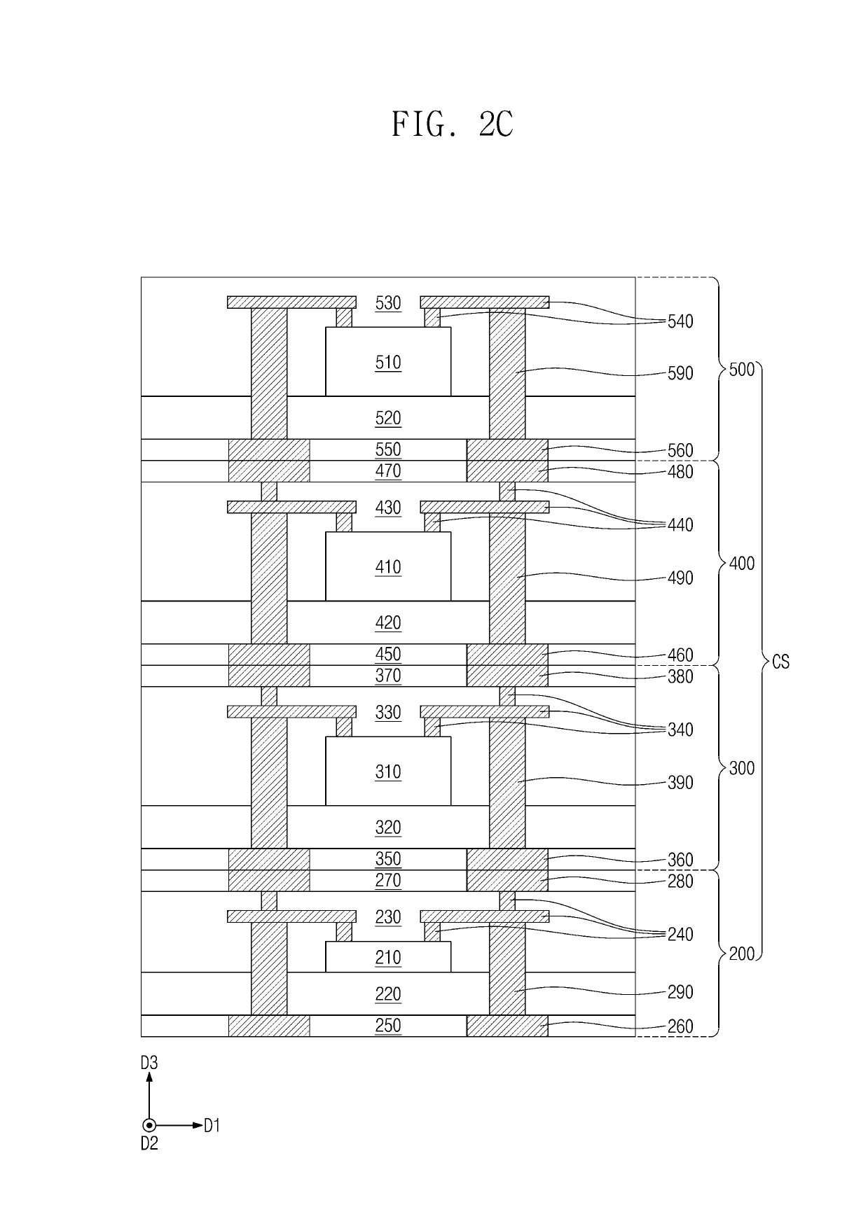

FIGS. 2A, 2B and 2C are diagrams for describing a method for manufacturing a semiconductor package according to FIGS. 1A and 1B.

Referring to FIG. 2A, the first fin pattern FP1 may be formed on the first substrate 320. The first lower channel structure LCH1, the first lower source/drain pattern LSD1, the first lower gate electrode LGE1, the first lower gate spacer LGS1, the first lower gate insulating layer LGI1, and the first lower gate capping pattern LGP1 may be formed on the first fin pattern FP1.

Referring to FIG. 2B, a first preliminary insulating structure 331 may be formed. The first preliminary insulating structure 331 may include an insulating material. The first interlayer insulating layer IL1 may be formed on the first preliminary insulating structure 331 and the first lower gate capping pattern LGP1. The first semiconductor layer SL1 may be formed on the first interlayer insulating layer IL1. The first upper channel structure UCH1, the first upper source/drain pattern USD1, the first upper gate electrode UGE1, the first upper gate spacer UGS1, the first upper gate insulating layer UGI1, the first upper gate capping pattern UGP1, and the first active contact AC1 may be formed on the first semiconductor layer SL1.

Referring to FIG. 2C, the first insulating structure 330 may be formed. Forming the first insulating structure 330 may include forming a second preliminary insulating structure on the first preliminary insulating structure 331. The first insulating structure 330 may include a first preliminary insulating structure 331 and the second preliminary insulating structure. In the process of forming the first insulating structure 330, the first through via 390 and the first conductive structure 340 may be formed together.

The first lower insulating layer 350 and the first lower pad 360 may be formed on a lower surface of the first substrate 320. The first upper insulating layer 370 and the first upper pad 380 may be formed on an upper surface of the first insulating structure 330.

The second logic chip 400 and the third logic chip 500 may be formed similarly to the first logic chip 300. The base chip 200, the first logic chip 300, the second logic chip 400, and the third logic chip 500 may be bonded to each other to form the chip structure CS. Referring to FIG. 1A, the chip structures CS may be mounted on the base structure 1 by using the bump 30. The underfill layer 20 may be formed. The molding layer 100 may be formed.

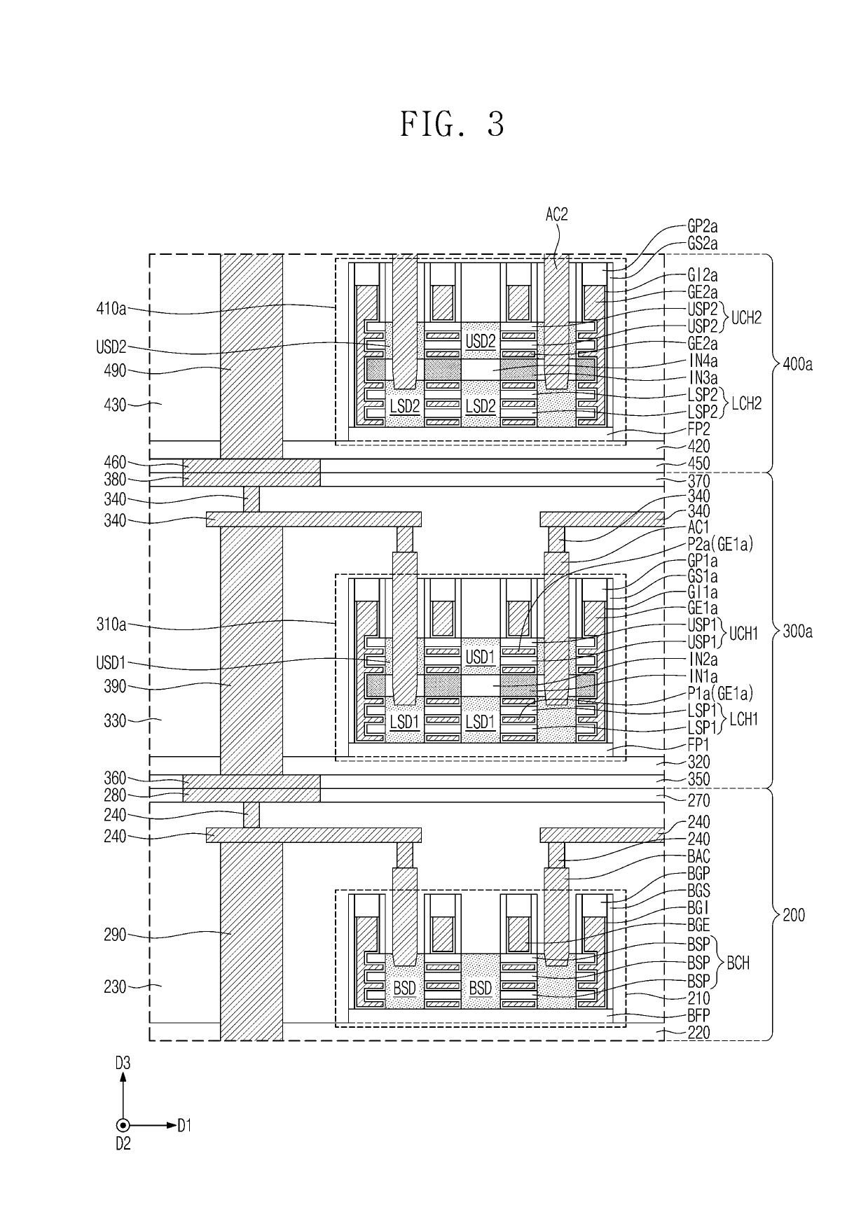

FIG. 3 is an enlarged cross-sectional view of a semiconductor package according to some embodiments. The semiconductor package according to FIG. 3 may be similar to the semiconductor package according to FIGS. 1A and 1B except as described below.

Referring to FIG. 3, a first logic cell structure 310a of a first logic chip 300a may include a first intervening insulating layer IN1a between the first lower semiconductor patterns LSP1 and the first upper semiconductor patterns USP1. The first logic cell structure 310a of the first logic chip 300a may include a second intervening insulating layer IN2a between the first lower source/drain pattern LSD1 and the first upper source/drain pattern USD1.

The first intervening insulating layer IN1a and the second intervening insulating layer IN2a may include different insulating materials. The first intervening insulating layer IN1a and the second intervening insulating layer IN2a may be in contact with each other.

The first logic cell structure 310a of the first logic chip 300a may include a first gate insulating layer GI1a in contact with the first intervening insulating layer IN1a, the first lower semiconductor patterns LSP1, and the first upper semiconductor patterns USP1.

The first logic cell structure 310a of the first logic chip 300a may include a first gate electrode GE1a in contact with the first gate insulating layer GI1a. The first gate electrode GE1a may overlap with the first lower semiconductor patterns LSP1 and the first upper semiconductor patterns USP1 in the third direction D3. The first gate electrode GE1a may include a first portion P1a between the first lower semiconductor patterns LSP1, and a second portion P2a between the first upper semiconductor patterns USP1.

The first logic cell structure 310a of the first logic chip 300a may include a first gate capping pattern GP1a on the first gate electrode GE1a.

The first active contact AC1 may penetrate the second intervening insulating layer IN2a in the third direction D3. A second logic cell structure 410a of a second logic chip 400a may include a third intervening insulating layer IN3a, a fourth intervening insulating layer IN4a, a second gate insulating layer GI2a, a second gate electrode GE2a, and a second gate capping pattern GP2a. Each of the third intervening insulating layer IN3a, the fourth intervening insulating layer IN4a, the second gate insulating layer GI2a, the second gate electrode GE2a, and the second gate capping pattern GP2a may have a structure similar to a structure of the first intervening insulating layer IN1a, the second intervening insulating layer IN2a, the first gate insulating layer GI1a, the first gate electrode GE1a, and the first gate capping pattern GP1a.

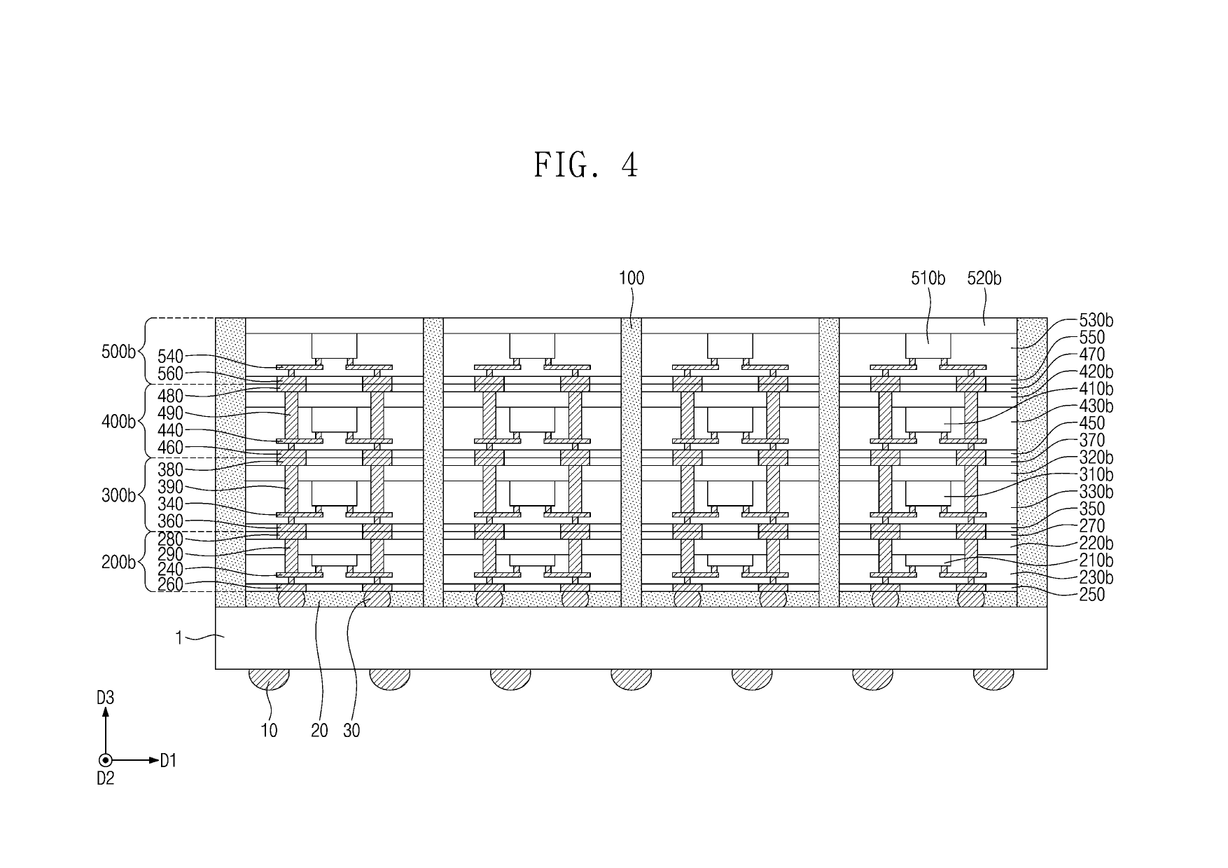

FIG. 4 is a cross-sectional view of a semiconductor package according to some embodiments. The semiconductor package according to FIG. 4 may be similar to the semiconductor package according to FIGS. 1A and 1B except as described below.

Referring to FIG. 4, a base chip 200b may include a base logic cell structure 210b connected to a lower surface of a base substrate 220b. A base insulating structure 230b may be provided on the lower surface of the base substrate 220b.

A first chip 300b may include a first logic cell structure 310b connected to a lower surface of a first substrate 320b. A first insulating structure 330b may be provided on the lower surface of the first substrate 320b.

A second chip 400b may include a second logic cell structure 410b connected to a lower surface of a second substrate 420b. A second insulating structure 430b may be provided on the lower surface of the second substrate 420b. A third chip 500b may include a third logic cell structure 510b connected to a lower surface of a third substrate 520b. A third insulating structure 530b may be provided on the lower surface of the third substrate 520b.

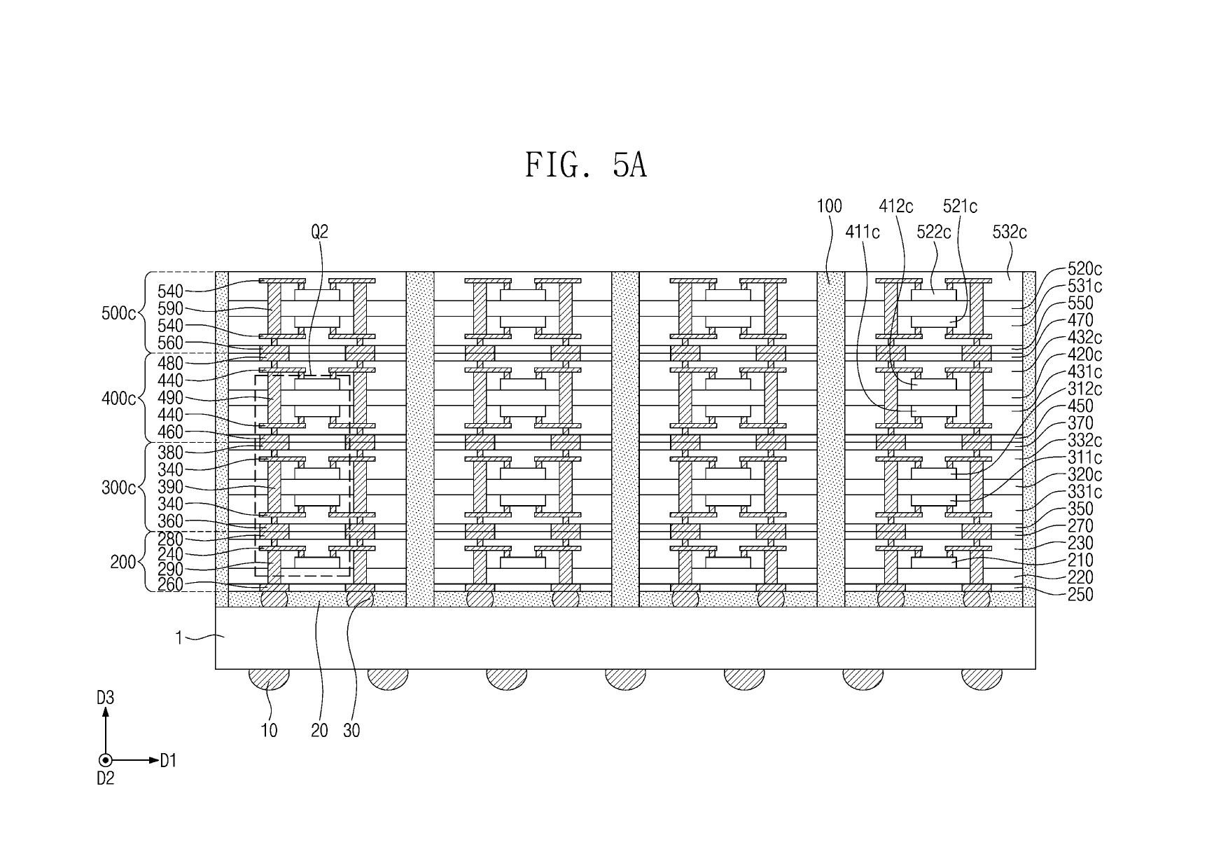

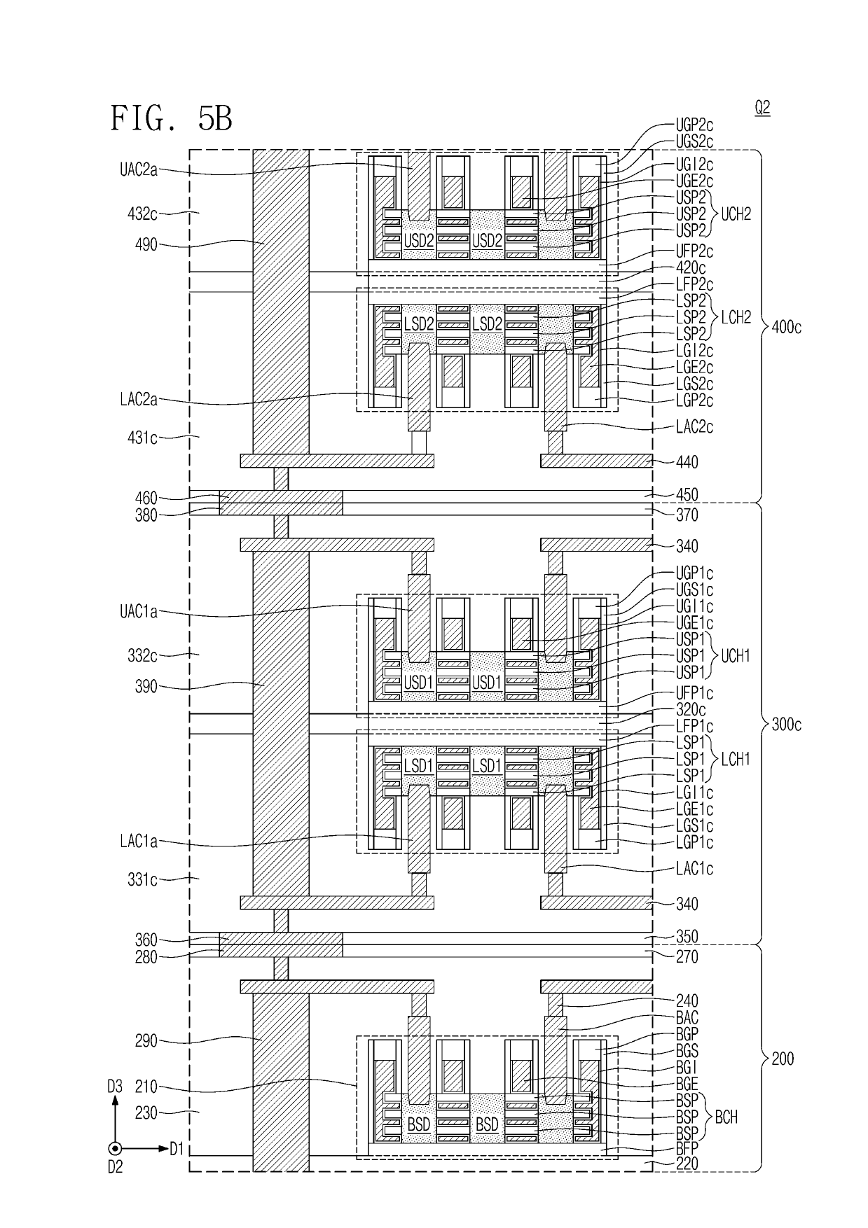

FIG. 5A is a cross-sectional view of a semiconductor package according to some embodiments. FIG. 5B is an enlarged view of a region Q2 of FIG. 5A. The semiconductor package according to FIGS. 5A and 5B may be similar to the semiconductor package according to FIG. 1A and 1B except as described below.

Referring to FIG. 5A, a first logic chip 300c may include a first lower logic cell structure 311c connected to a lower surface of a first substrate 320c and a first upper logic cell structure 312c connected to an upper surface of the first substrate 320c. The first logic chip 300c may include a first lower insulating structure 331c on the lower surface of the first substrate 320c and a first upper insulating structure 332c on the upper surface of the first substrate 320c.

A second logic chip 400c may include a second lower logic cell structure 411c connected to a lower surface of a second substrate 420c and a second upper logic cell structure 412c connected to an upper surface of the second substrate 420c. The second logic chip 400c may include a second lower insulating structure 431c on the lower surface of the second substrate 420c and a second upper insulating structure 432c on the upper surface of the second substrate 420c.

A third logic chip 500c may include a third lower logic cell structure 521c connected to a lower surface of a third substrate 520c and a third upper logic cell structure 522c connected to an upper surface of the third substrate 520c. The third logic chip 500c may include a third lower insulating structure 531c on the lower surface of the third substrate 520c and a third upper insulating structure 532c on the upper surface of the third substrate 520c.

Referring to FIG. 5B, the first lower logic cell structure 311c of the first logic chip 300c may include a first lower fin pattern LFP1c, a first lower gate insulating layer LGI1c, a first lower gate electrode LGE1c, a first lower gate capping pattern LGP1c, and a first lower active contact LAC1c.

The first lower fin pattern LFP1c may be a portion of the first substrate 320c. A portion protruding from the lower surface of the first substrate 320c in a direction opposite to the third direction D3 may be defined as the first lower fin pattern LFP1c.

The first lower source/drain pattern LSD1 may be connected to a lower surface of the first lower fin pattern LFP1c. The first lower gate electrode LGE1c may be provided on an upper surface of the first lower gate capping pattern LGP1c.

The first lower active contact LAC1c may be connected to a lower portion of the first lower source/drain pattern LSD1.

The first upper logic cell structure 312c of the first logic chip 300c may include a first upper fin pattern UFP1c, a first upper gate insulating layer UGI1c, a first upper gate electrode UGE1c, a first upper gate capping pattern UGP1c, and a first upper active contact UAC1c.

The first upper fin pattern UFP1c may be a portion of the first substrate 320c. A portion protruding from an upper surface of the first substrate 320c in the third direction D3 may be defined as the first upper fin pattern UFP1c.

The first upper source/drain pattern USD1 may be connected to an upper surface of the first upper fin pattern UFP1c. The first upper gate capping pattern UGP1c may be provided on an upper surface of the first upper gate electrode UGE1c.

The first upper active contact UAC1c may be connected to an upper portion of the first upper source/drain pattern USD1.

The first upper semiconductor patterns USP1 of the first upper channel structure UCH1 and the first lower semiconductor patterns LSP1 of the first lower channel structure LCH1 may be spaced apart from each other in the third direction D3 with the first substrate 320c interposed therebetween. The first upper source/drain pattern USD1 and the first lower source/drain patterns LSD1 may be spaced apart from each other in the third direction D3 with the first substrate 320c interposed therebetween.

The second lower logic cell structure 411c of the second logic chip 400c may include a second lower fin pattern LFP2c, a second lower gate insulating layer LGI2c, a second lower gate electrode LGE2c, a second lower gate capping pattern LGP2c, and a second lower active contact LAC2c.

The second lower logic cell structure 411c of the second logic chip 400c may have a structure similar to a structure of the first lower logic cell structure 311c of the first logic chip 300c.

The second upper logic cell structure 412c of the second logic chip 400c may include a second upper fin pattern UFP2c, a second upper gate insulating layer UGI2c, a second upper gate electrode UGE2c, a second upper gate capping pattern UGP2c, and a second upper active contact UAC2c.

The second upper logic cell structure 412c of the second logic chip 400c may have a structure similar to a structure of the first upper logic cell structure 312c of the first logic chip 300c.

The second lower source/drain pattern LSD2, the first upper source/drain pattern USD1, the second lower semiconductor patterns LSP2, and the first upper semiconductor patterns USP1 may be disposed between the first substrate 320c and the second substrate 420c.

The first substrate 320c and the second substrate 420c may be disposed between the first lower semiconductor patterns LSP1 and the second upper semiconductor patterns USP2. In a semiconductor package according to some embodiments, each of the logic chips may include the upper logic cell structure and the lower logic cell structure. Accordingly, a thickness of the chip structure in the third direction D3 may be reduced, and a size of the semiconductor package may be reduced. Accordingly, a degree of integration of the semiconductor package may be improved, packaging stress may be alleviated, and heat dissipation may be improved.

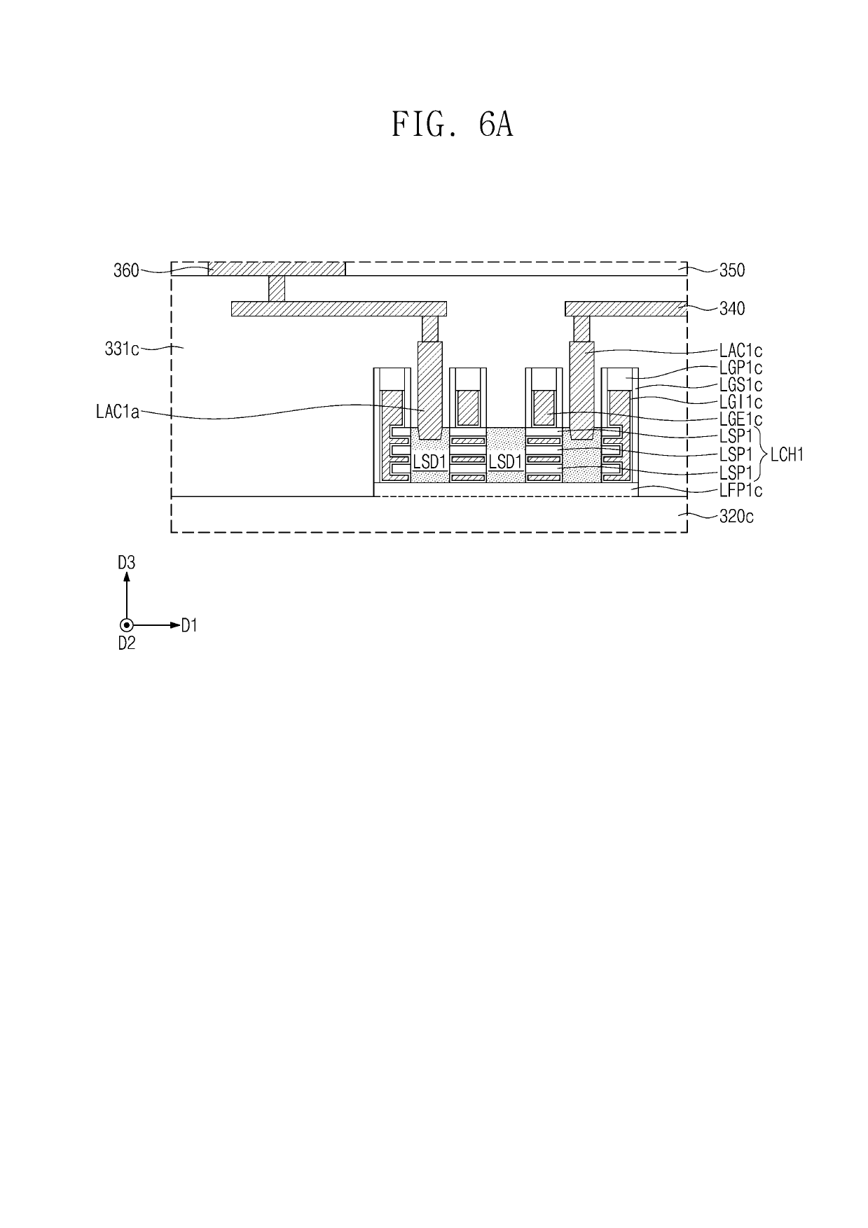

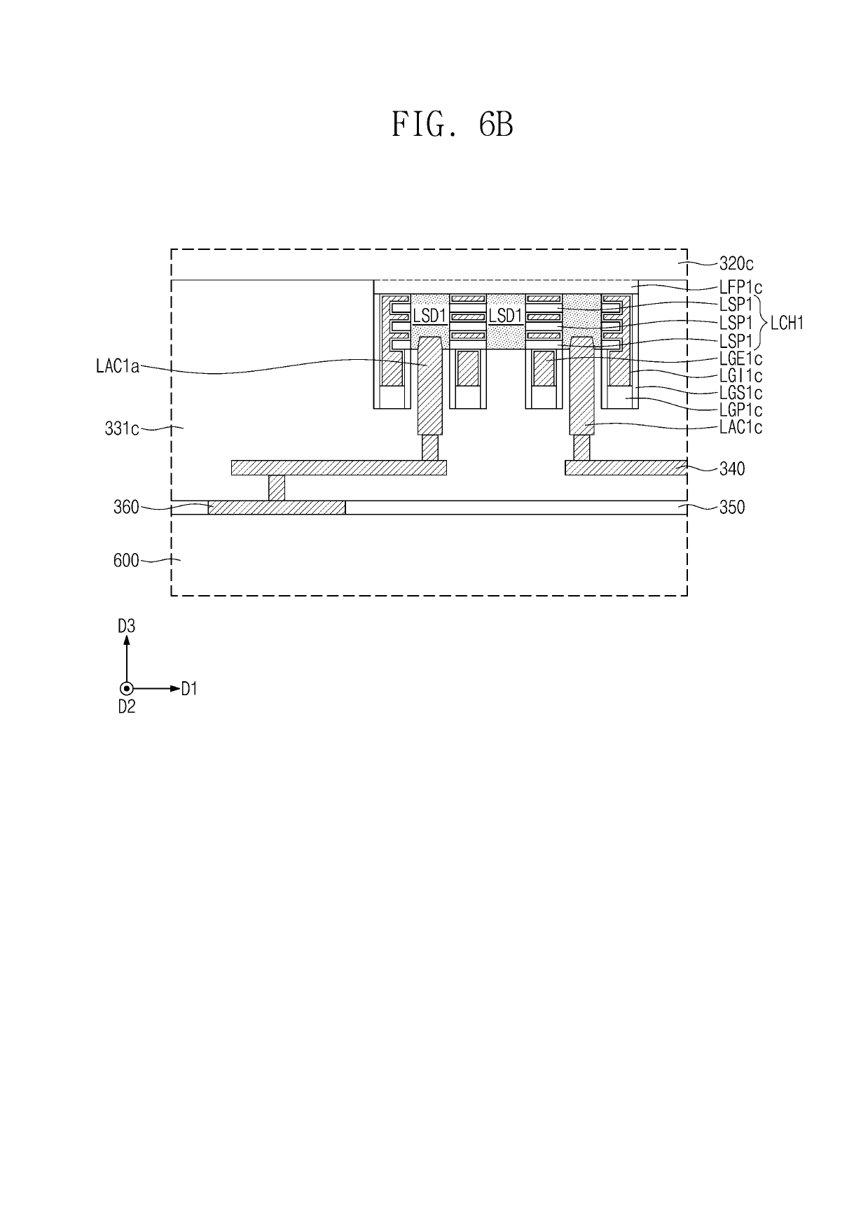

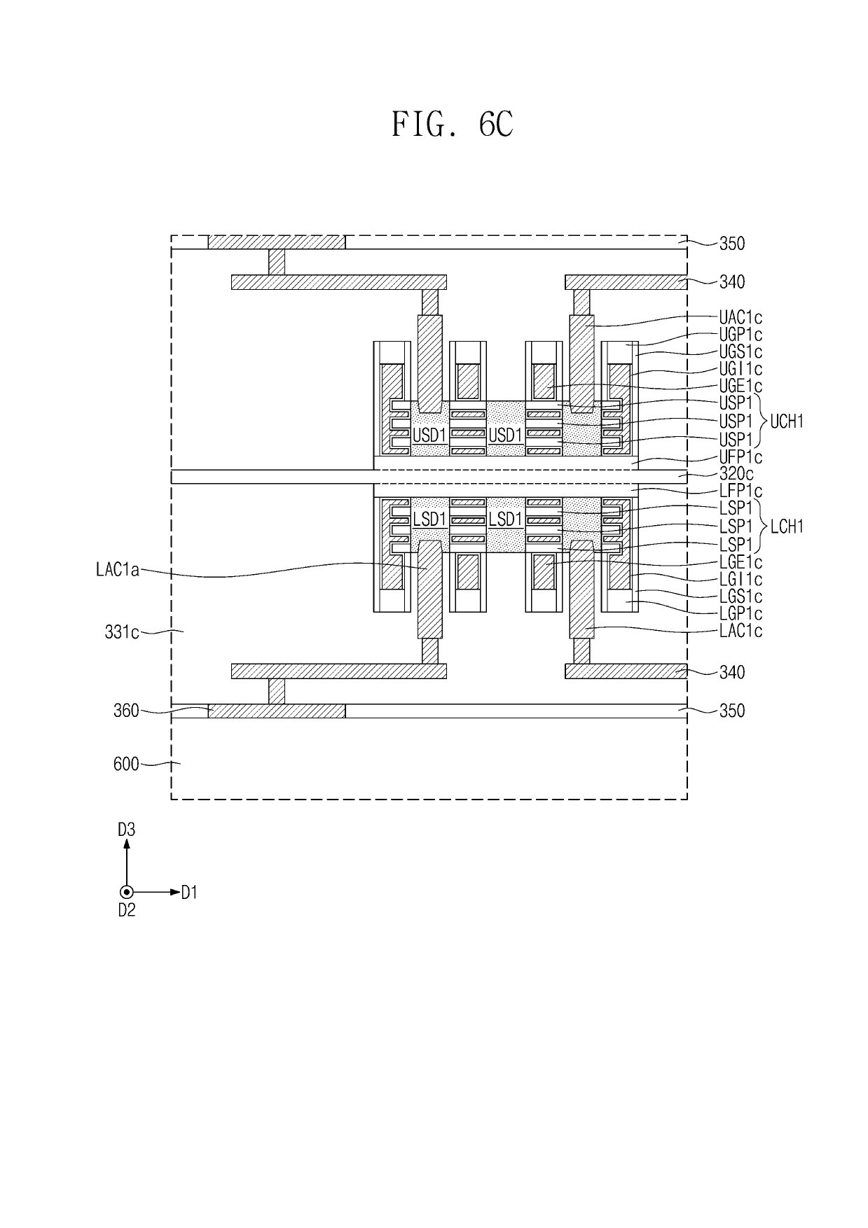

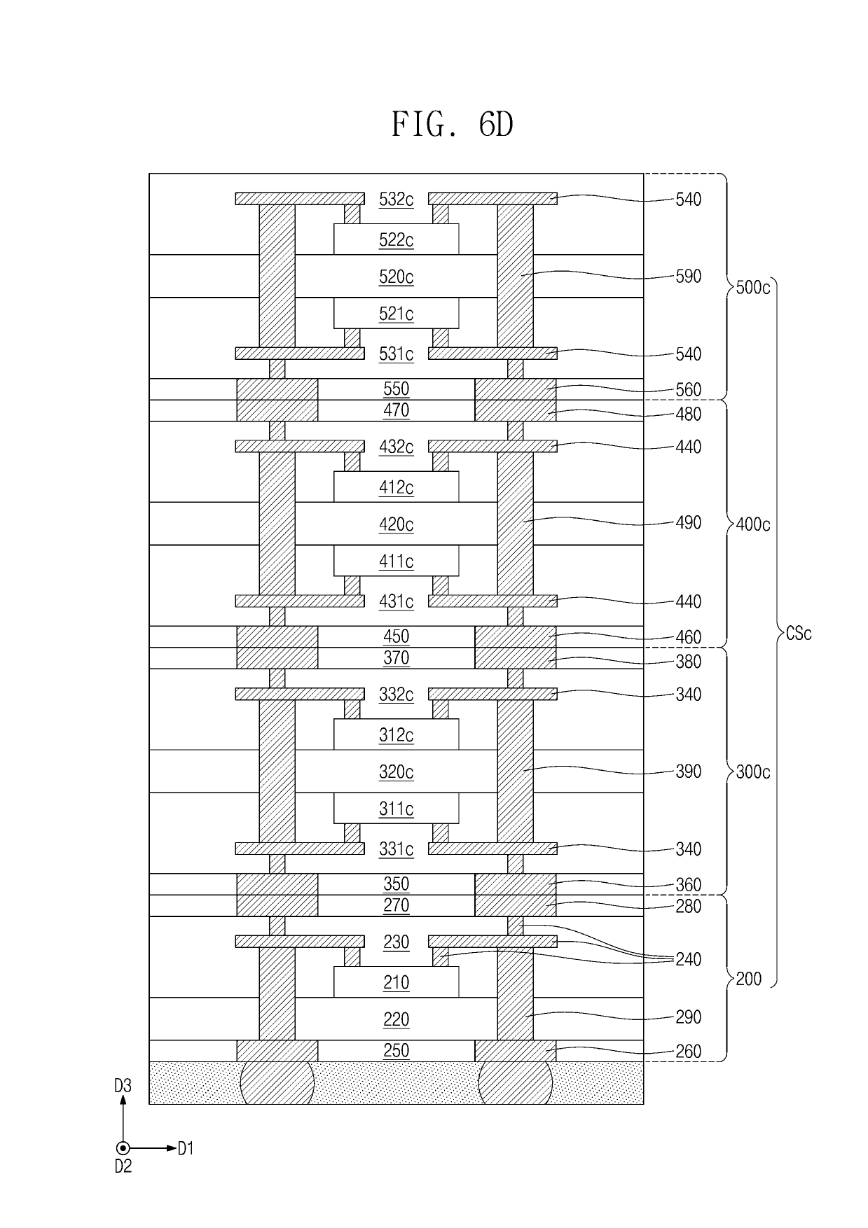

FIGS. 6A, 6B, 6C and 6D are diagrams for describing a method of manufacturing a semiconductor package according to FIGS. 5A and 5B.

Referring to FIG. 6A, the first lower fin pattern LFP1c may be formed on a first surface of the first substrate 320c. The first lower channel structure LCH1, the first lower source/drain pattern LSD1, the first lower gate electrode LGE1c, the first lower gate spacer LGS1c, the first lower gate insulating layer LGI1c, and the first lower gate capping pattern LGP1c may be formed on the first lower fin pattern LFP1c.

The first lower active contact LAC1c, the first conductive structure 340, and the first lower insulating structure 331c may be formed. The first lower insulating layer 350 and the first lower pad 360 may be formed.

Referring to FIG. 6B, the first substrate 320c may be inverted, and the first lower insulating layer 350 may be attached to a carrier substrate 600.

Referring to FIG. 6C, the first upper fin pattern UFP1c may be formed on a second surface of the first substrate 320c. The second surface may be opposite to the first surface. The first upper channel structures UCH1, the first upper source/drain pattern USD1, the first upper gate electrode UGE1c, the first upper gate spacer UGS1c, the first top gate insulating layer UGI1c, and the first upper gate capping pattern UGP1c may be formed on the first upper fin pattern UFP1c.

The first upper active contact UAC1c, the first conductive structure 340, and the first upper insulating structure 332c may be formed. The first upper insulating layer 370 and the first upper pad 380 may be formed.

Referring to FIG. 6D, the second logic chip 400c and the third logic chip 500c may be formed similarly to the first logic chip 300c.

Forming the second logic chip 400c may include forming the second lower fin pattern LFP2c (see FIG. 5B) on a first surface of the second substrate 420c, forming the second lower source/drain pattern LSD2 (see FIG. 5B), inverting the second substrate 420C, forming the second upper fin pattern UFP2c (see FIG. 5B) on a second surface opposite the first surface of the second substrate 420c, and forming the second upper source/drain pattern USD2 (see FIG. 5B), on the second upper fin pattern UFP2c.

The base chip 200, the first logic chip 300c, the second logic chip 400c, and the third logic chip 500c may be bonded to each other to form a chip structure CSc. In some embodiments, the base chip 200, the first logic chip 300c, the second logic chip 400c, and the third logic chip 500c may be connected to each other by at least one bump.

Referring to FIG. 5A, the chip structure CSc may be mounted on the base structure 1 using the bump 30. The underfill layer 20 may be formed. The molding layer 100 may be formed.

According to some embodiments of the present disclosure, a method of fabricating a semiconductor package may include forming a first logic chip. The forming the first logic chip includes: forming a first lower fin pattern on a first surface of a first substrate; forming a first lower source/drain pattern on the first lower fin pattern; inverting the first substrate; forming a first upper fin pattern on a second surface opposite the first surface of the first substrate; and forming a first upper source/drain pattern on the first upper fin pattern.

According to some embodiments of the present disclosure, the method of fabricating the semiconductor package may further include forming a second logic chip; and connecting the first logic chip and the second logic chip. The forming the second logic chip includes: forming a second lower fin pattern on a first surface of a second substrate; forming a second lower source/drain pattern on the second lower fin pattern; inverting the second substrate; forming a second upper fin pattern on a second surface opposite the first surface of the second substrate; and forming a second upper source/drain pattern on the second upper fin pattern.

According to some embodiments of the present disclosure, the connecting the first logic chip to the second logic chip may include bonding the first logic chip and the second logic chip.

According to some embodiments of the present disclosure, the first lower source/drain pattern and the first upper source/drain pattern may be spaced apart from each other with the first substrate interposed therebetween.

According to some embodiments of the present disclosure, the forming the first logic chip may further include forming a through via penetrating the first substrate.

According to some embodiments of the present disclosure, a method of fabricating a semiconductor package may include: forming a first logic chip; forming a second logic chip; and connecting the first logic chip and the second logic chip. The first logic chip includes: a first lower channel structure; and a first lower source/drain pattern connected to the first lower channel structure. The second logic chip includes: a second lower channel structure; a second lower source/drain pattern connected to the second lower channel structure; a second upper channel structure overlapping with the second lower channel structures; and a second upper source/drain pattern connected to the second upper channel structure.

In a semiconductor package in accordance with embodiments of the present disclosure, a thickness of the chip structure may be reduced, and a size of the semiconductor package may be reduced. Accordingly, a degree of integration of the semiconductor package may be improved, packaging stress may be alleviated, and heat dissipation may be improved.

While non-limiting example embodiments of the present disclosure have been described above with reference to the accompanying drawings, a person skilled in the art may understand that many modifications and variations are made without departing from the spirit and scope of the present disclosure. Accordingly, the example embodiments of the present disclosure should be considered in all respects as illustrative and not restrictive.

What is claimed is:

1. A semiconductor package comprising:
a first logic chip; and
a second logic chip overlapping with the first logic chip,
wherein the first logic chip comprises:
a first lower channel structure;
a first lower source/drain pattern connected to the first lower channel structure;
a first upper channel structure overlapping with the first lower channel structure; and
a first upper source/drain pattern connected to the first upper channel structure, and
wherein the second logic chip comprises:
a second lower channel structure;
a second lower source/drain pattern connected to the second lower channel structure;
a second upper channel structure overlapping with the second lower channel structure; and
a second upper source/drain pattern connected to the second upper channel structure.

2. The semiconductor package of claim 1, wherein the first logic chip further comprises a substrate,
wherein the substrate is between the first lower channel structure and the first upper channel structure, and
wherein the substrate is between the first lower source/drain pattern and the first upper source/drain pattern.

3. The semiconductor package of claim 2, wherein the substrate comprises:
a lower fin pattern connected to the first lower source/drain pattern; and
an upper fin pattern connected to the first upper source/drain pattern.

4. The semiconductor package of claim 3, wherein the upper fin pattern protrudes from an upper surface of the substrate, and
wherein the lower fin pattern protrudes from a lower surface of the substrate.

5. The semiconductor package of claim 2, wherein the first logic chip further comprises:
an upper active contact connected to an upper portion of the first upper source/drain pattern; and
a lower active contact connected to a lower portion of the first lower source/drain pattern.

6. The semiconductor package of claim 2, wherein the first logic chip further comprises a through via penetrating the substrate.

7. The semiconductor package of claim 1, further comprising a base chip overlapping with the first logic chip and the second logic chip,
wherein a thickness of the base chip is less than a thickness of the first logic chip and a thickness of the second logic chip.

8. A semiconductor package comprising:
a base structure;
a first logic chip electrically connected to the base structure; and
a second logic chip overlapping with the first logic chip, and electrically connected to the base structure,
wherein the first logic chip comprises:
first lower semiconductor patterns;
a first lower source/drain pattern connected to the first lower semiconductor patterns;
first upper semiconductor patterns overlapping with the first lower semiconductor patterns; and
a first upper source/drain pattern connected to the first upper semiconductor patterns, and
wherein the second logic chip comprises:
second lower semiconductor patterns;
a second lower source/drain pattern connected to the second lower semiconductor patterns;
second upper semiconductor patterns overlapping with the second lower semiconductor patterns; and
a second upper source/drain pattern connected to the second upper semiconductor patterns.

9. The semiconductor package of claim 8, wherein the first logic chip further comprises a semiconductor layer between the first lower semiconductor patterns and the first upper semiconductor patterns, and between the first lower source/drain pattern and the first upper source/drain pattern, and
wherein the first upper source/drain pattern is in contact with the semiconductor layer.

10. The semiconductor package of claim 9, wherein the first logic chip further comprises:
a lower gate insulating layer in contact with the first lower semiconductor patterns;
a lower gate electrode in contact with the lower gate insulating layer;
an upper gate insulating layer in contact with the first upper semiconductor patterns; and
an upper gate electrode in contact with the upper gate insulating layer,
wherein the semiconductor layer is between the lower gate electrode and the upper gate electrode.

11. The semiconductor package of claim 8, wherein the first logic chip further comprises an active contact connected to the first lower source/drain pattern and the first upper source/drain pattern.

12. The semiconductor package of claim 8, wherein the first logic chip further comprises a gate electrode overlapping with the first upper semiconductor patterns and the second upper semiconductor patterns, and
wherein the gate electrode comprises:
a first portion between the first lower semiconductor patterns; and
a second portion between the first upper semiconductor patterns.

13. The semiconductor package of claim 8, wherein the first logic chip further comprises a first intervening insulating layer between the first upper semiconductor patterns and the first lower semiconductor patterns.

14. The semiconductor package of claim 13, wherein the first logic chip further comprises a second intervening insulating layer between the first upper source/drain pattern and the first lower source/drain pattern, and
wherein a material of the first intervening insulating layer is different from a material of the second intervening insulating layer.

15. The semiconductor package of claim 14, wherein the first intervening insulating layer and the second intervening insulating layer are in contact with each other.

16. A semiconductor package comprising:
a base structure;
a chip structure electrically connected to the base structure; and
a molding layer surrounding the chip structure in a horizontal direction,
wherein the chip structure comprises:
a base chip;
a first logic chip overlapping with the base chip; and
a second logic chip overlapping with the base chip and the first logic chip,
wherein the first logic chip comprises:
a first substrate;
a first lower source/drain pattern connected to the first substrate;
first lower semiconductor patterns connected to the first lower source/drain pattern;
a first upper source/drain pattern overlapping with the first lower source/drain pattern; and
first upper semiconductor patterns connected to the first upper source/drain pattern, and
wherein the second logic chip comprises:
a second substrate;
a second lower source/drain pattern connected to the second substrate;
second lower semiconductor patterns connected to the second lower source/drain pattern;
a second upper source/drain pattern overlapping with the second lower source/drain pattern; and
second upper semiconductor patterns connected to the second upper source/drain pattern.

17. The semiconductor package of claim 16, wherein the first logic chip further comprises a first through via penetrating the first substrate,
wherein the second logic chip further comprises a second through via penetrating the second substrate.

18. The semiconductor package of claim 16, wherein the first substrate is between the first lower source/drain pattern and the first upper source/drain pattern, and between the first lower semiconductor patterns and the first upper semiconductor patterns.

19. The semiconductor package of claim 18, wherein the second lower source/drain pattern, the first upper source/drain pattern, the second lower semiconductor patterns, and the first upper semiconductor patterns are between the first substrate and the second substrate.

20. The semiconductor package of claim 16, wherein the first lower source/drain pattern, the first upper source/drain pattern, the first lower semiconductor patterns, and the first upper semiconductor patterns are between the first substrate and the second substrate.
